(19) United States
(12) Patent Application Publication
(10) Pub. No.: US 2025/0393307 A1
(43) Pub. Date: Dec. 25, 2025

(54) DISPLAY PANEL AND MANUFACTURING METHOD THEREOF, AND DISPLAY APPARATUS

(71) Applicant: Tianma Advanced Display Technology Institute (Xiamen) Co., Ltd., Xiamen (CN)

(72) Inventors: Xueling LI, Xiamen (CN); Zhenyu JIA, Xiamen (CN); Lanshu YE, Xiamen (CN)

(21) Appl. No.: 19/307,071

(22) Filed: Aug. 22, 2025

(30) Foreign Application Priority Data
Apr. 30, 2025 (CN) 202510564556.1

(51) Int. Cl. H10D 86/40

(52) U.S. Cl. CPC H10D 86/441

(57) ABSTRACT

Provided is a display panel. The display panel includes: a substrate, signal lines, pads, and side traces. The substrate includes a first surface and a second surface opposite to each other, and a first side face located between the first surface and the second surface. The signal lines and the pads are located on the first surface, the pads are located on a side of the signal lines close to the first side face, and at least part of the pads are connected to the signal lines. The side traces are arranged on the first surface, the first side face, and the second surface, and the side traces are connected to the pads. The pads include a first pad and a second pad arranged along a first direction, and along the first direction, a width of the first pad is greater than a width of the second pad.

### CROSS-REFERENCE TO RELATED APPLICATION

The present application claims priority to Chinese Patent Application No. 202510564556.1, filed on Apr. 30, 2025, the content of which is incorporated herein by reference in its entirety.

### TECHNICAL FIELD

The present disclosure relates to the field of display technologies and, in particular, to a display panel and a manufacturing method thereof, and a display apparatus.

### BACKGROUND

At present, side traces can be used to narrow the borders of the display panel. In this type of display panel, the signal lines on the front surface of the substrate are connected to the pads at the lower edge of the substrate, and the side traces overlap with the pads and extend from the front surface and the side face of the substrate to the back surface, so as to be connected to the binding pins configured to bind the circuit board on the back surface.

In the manufacturing process of the display panel, it is usually necessary to perform some tests on the display panel. During testing, the pads may be damaged by the probe of the test device, thereby affecting the reliability of its connection with the side traces.

### SUMMARY

Embodiments of the present disclosure provides a display panel and a manufacturing method thereof, and a display apparatus, for reducing the risk of the pads being scratched.

In a first aspect, an embodiment of the present disclosure provides a display panel, including: a substrate, a plurality of signal lines, a plurality of pads, and a plurality of side traces. The substrate includes a first surface and a second surface opposite to each other, and a first side face located between the first surface and the second surface. The plurality of signal lines and the plurality of pads are located on the first surface, the plurality of pads are located on a side of the plurality of signal lines close to the first side face, and at least part of the plurality of pads are electrically connected to the plurality of signal lines respectively. The plurality of side traces are arranged on the first surface, the first side face, and the second surface, and the side traces are electrically connected to the plurality of pads respectively. The plurality of pads include first pads and second pads arranged along a first direction, and along the first direction, a width of one of the first pads is greater than a width of one of the second pads.

In a second aspect, based on the same inventive concept, an embodiment of the present disclosure provides a method for manufacturing a display panel, including cutting a motherboard to form a display panel. The display panel includes: a substrate, a plurality of signal lines, a plurality of pads, and a plurality of side traces. The substrate includes a first surface and a second surface opposite to each other, and a first side face located between the first surface and the second surface. The plurality of signal lines and the plurality of pads are located on the first surface, the plurality of pads are located on a side of the plurality of signal lines close to the first side face, and at least part of the plurality of pads are electrically connected to the plurality of signal lines respectively. The plurality of pads include first pads and second pads arranged along a first direction, and along the first direction, a width of one of the second pads is less than a width of one of the first pads. The plurality of side traces are arranged on the first surface, the first side face, and the second surface, and the side traces are electrically connected to the plurality of pads respectively.

In a third aspect, based on the same inventive concept, an embodiment of the present disclosure provides a display apparatus, including a display panel. The display panel includes: a substrate, a plurality of signal lines, a plurality of pads, and a plurality of side traces. The substrate includes a first surface and a second surface opposite to each other, and a first side face located between the first surface and the second surface. The plurality of signal lines and the plurality of pads are located on the first surface, the plurality of pads are located on a side of the plurality of signal lines close to the first side face, and at least part of the plurality of pads are electrically connected to the plurality of signal lines respectively. The plurality of side traces are arranged on the first surface, the first side face, and the second surface, and the side traces are electrically connected to the plurality of pads respectively. The plurality of pads include first pads and second pads arranged along a first direction, and along the first direction, a width of one of the first pads is greater than a width of one of the second pads.

### BRIEF DESCRIPTION OF DRAWINGS

To clearly illustrate the technical solutions of the embodiments of the present disclosure or the related art, the drawings required in the embodiments or the prior art are briefly introduced below. It is appreciated that the drawings described below are only some embodiments of the present disclosure. For those skilled in the art, other drawings can be obtained according to these drawings without any creative effort.

FIG. 1 is a structural schematic diagram of a display panel according to some embodiments of the present disclosure;

FIG. 2 is a schematic diagram of a display panel in FIG. 1 with a first surface of a substrate facing upward;

FIG. 3 is a schematic diagram of a display panel in FIG. 1 with a second surface of a substrate facing upward;

FIG. 4 is a top view of a display panel according to some embodiments of the present disclosure;

FIG. 5 is a top view of another display panel according to some embodiments of the present disclosure;

FIG. 6 is a top view of another display panel according to some embodiments of the present disclosure;

FIG. 7 is a top view of another display panel according to some embodiments of the present disclosure;

FIG. 8 is a schematic diagram of a display panel according to the related art in a manufacturing process;

FIG. 9 is a schematic diagram of a display panel in a manufacturing process according to some embodiments of the present disclosure;

FIG. 10 is a structural schematic diagram of another display panel according to some embodiments of the present disclosure;

FIG. 11 is a structural schematic diagram of another display panel according to some embodiments of the present disclosure;

FIG. 12 is a structural schematic diagram of another display panel according to some embodiments of the present disclosure;

FIG. 13 is a structural schematic diagram of another display panel according to some embodiments of the present disclosure;

FIG. 14 is a structural schematic diagram of a further display panel according to some embodiments of the present disclosure;

FIG. 15 is a structural schematic diagram of a pad according to some embodiments of the present disclosure;

FIG. 16 is a structural schematic diagram of a film layer of a display panel according to some embodiments of the present disclosure;

FIG. 17 is a structural schematic diagram of another display panel according to some embodiments of the present disclosure;

FIG. 18 is a structural schematic diagram of another display panel according to some embodiments of the present disclosure;

FIG. 19 is a partial schematic diagram of a method for manufacturing a display panel according to some embodiments of the present disclosure;

FIG. 20 is a partial schematic diagram of another method for manufacturing a display panel according to some embodiments of the present disclosure; and

FIG. 21 is a structural schematic diagram of a display apparatus according to some embodiments of the present disclosure.

### DESCRIPTION OF EMBODIMENTS

To better understand the technical solutions of the present disclosure, embodiments of the present disclosure are described in detail below in conjunction with the drawings.

It should be clarified that the described embodiments are only some, rather than all, of embodiments of the present disclosure. According to embodiments of the present disclosure, all other embodiments obtained by those skilled in the art without any creative effort shall fall within the protection scope of the present disclosure.

The terms used in the embodiments of the present disclosure are only for the purpose of describing specific embodiments and are not intended to limit the present disclosure. The singular forms “a/an”, “said” and “the” used in the embodiments of the present disclosure and the claims are intended to include plural forms unless the context clearly indicates otherwise.

It should be understood that the term “and/or” herein is only used to describe the associated relationship of associated objects, indicating that three relationships may exist. For example, A and/or B can represent: A exists alone, A and B exist at the same time, and B exists alone. In addition, the character “/” herein generally indicates that the associated objects are in an “or” relationship.

Before describing the technical solutions according to the embodiments of the present disclosure, the problems existing in the related art are first described.

A display panel includes a substrate, and the substrate includes a front surface, a side face, and a back surface. The front surface is a surface of the substrate facing a light-emitting side of the display panel, and the back surface is a surface of the substrate facing away from the light-emitting side of the display panel.

A plurality of signal lines and a plurality of pads are arranged on the front surface of the substrate, and at least part of the pads are electrically connected to the signal lines. In the related art, the pads are designed with equal dimensions, that is, the widths of different pads are equal along the arrangement direction of the plurality of pads.

The display panel further includes side traces, which overlap with the pads on the front surface, extends to the back surface through the side face, and are electrically connected to binding pins configured to bind a circuit board on the back surface, thereby forming a signal transmission path between the circuit board and the signal lines.

In the manufacturing process of the display panel, after forming the signal lines and the pads, it is usually necessary to use an external test device to test the resistance and other parameters of the signal lines to detect whether there is a short circuit or open circuit in the signal lines, and then to detect whether the display panel is qualified.

This detection process can be performed before the formation of the side traces. For example, on the production line of the display panel, after forming the signal lines and the pads, the signal lines can be detected as above before the formation of the side traces. During the detection process, for example, a probe of the test device is placed on the pad connected to a certain signal line, and another probe is placed on the pad connected to another signal line to detect whether there is an abnormal electrical signal between the two signal lines. If there is, it means that there is a short circuit between the two signal lines.

This detection process can also be performed after the formation of the side traces. For example, after the display panel leaves the factory, it may be returned to the factory based on customer feedback, and the signal lines need to be retested after return. During retesting, because the side traces have been formed in the display panel, the probe of the test device is placed on the side trace above the pad to complete the detection.

However, the inventor has found that in the above detection process, directly placing the probe on the pad or the side trace can easily damage the pad or the side trace.

For example, when detecting the signal lines on the production line, the probe is directly placed on the pad, and there is a risk of scratching the pad. If the pad is scratched, it will cause poor connection between the pad and the side trace during the subsequent formation of the side traces, thereby affecting the display. When retesting the signal lines after the display panel is returned to the factory, the probe is placed on the side trace above the pad, which may also cause poor connection between the side trace and the pad due to the scratches by the probe, thereby affecting the display.

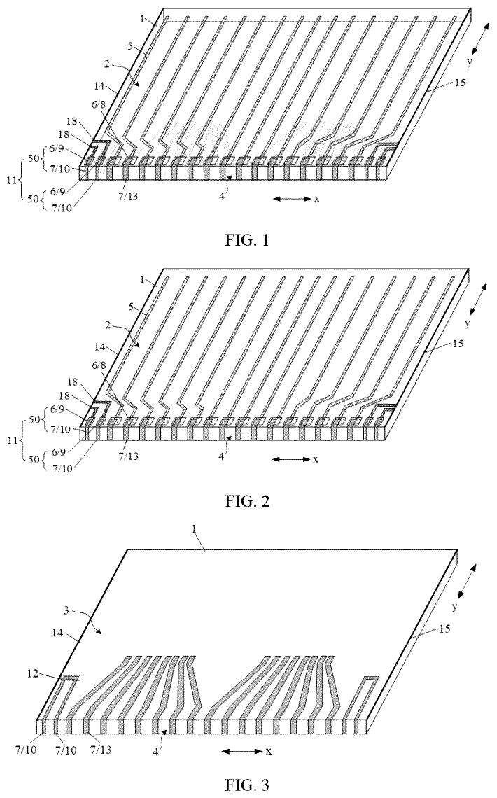

In view of the above, an embodiment of the present disclosure provides a display panel. As shown in FIG. 1 to FIG. 3, where FIG. 1 is a structural schematic diagram of a display panel according to some embodiments of the present disclosure, FIG. 2 is a schematic diagram of a display panel in FIG. 1 with a first surface of a substrate facing upward, and FIG. 3 is a schematic diagram of a display panel in FIG. 1 with a second surface of a substrate facing upward, the display panel includes a substrate 1, and the substrate 1 includes a first surface 2 and a second surface 3 opposite to each other, and a first side face 4 located between the first surface 2 and the second surface 3.

The first surface 2 is a surface of the substrate 1 facing a light-emitting side of the display panel, the second surface 3 is a surface of the substrate 1 facing a backlight side of the display panel, and the first side face 4 is connected between the first surface 2 and the second surface 3.

The display panel further includes a plurality of signal lines 5 and a plurality of pads 6 located on the first surface 2, and the pads 6 are located on a side of the signal lines 5 close to the first side face 4. At least part of the pads 6 are electrically connected to the signal lines 5. In other words, the display panel includes a display area and a first non-display area, the first non-display area is located on a side of the display area close to the first side face 4, the signal lines 5 is at least located in the display area, and the pads 6 are located in the first non-display area. The signal lines 5 extend from the display area to the first non-display area, and are connected to the pads 6 in the first non-display area. The signal lines 5 are traces for driving the display, and may include data lines, power lines, clock lines and other lines.

The display panel further includes a plurality of side traces 7 arranged on the first surface 2, the first side face 4 and the second surface 3, and the side traces 7 are electrically connected to the pads 6. For example, each of the side traces 7 overlaps with one pad 6 on the first surface 2, and then extends to the second surface 3 through the first side face 4, and is electrically connected to a binding pin configured to bind the circuit board on the second surface 3, thereby forming a signal transmission path between the circuit board and the signal line 5.

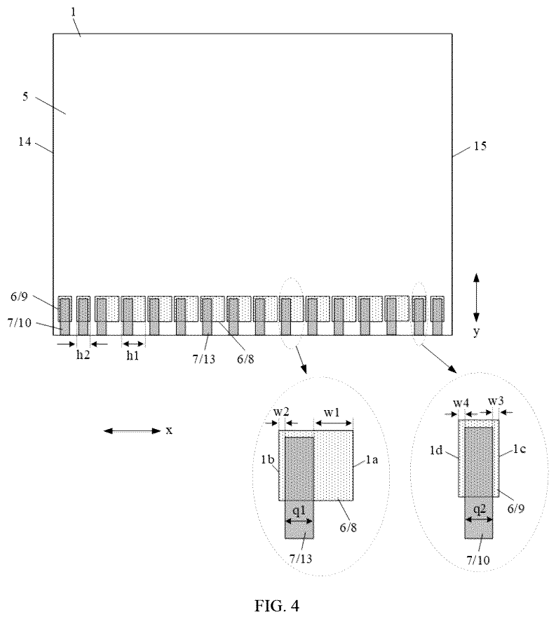

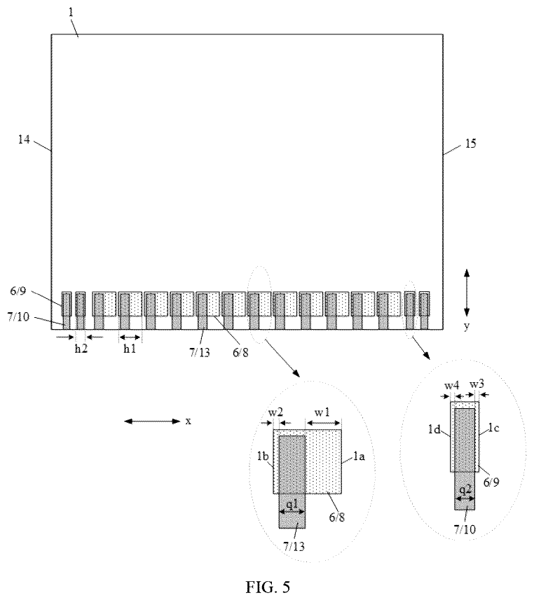

Referring to FIG. 4 and FIG. 5, where FIG. 4 is a top view of a display panel according to some embodiments of the present disclosure, and FIG. 5 is a top view of another display panel according to some embodiments of the present disclosure, the pads 6 include a first pad 8 and a second pad 9 arranged along a first direction x, and a width h1 of the first pad 8 is greater than a width h2 of the second pad 9 along the first direction x.

The width of the pad 6 along the first direction x is referred to as the width of the pad 6 hereinafter.

As mentioned above, in the related art, the widths of the plurality of pads are uniformly designed, and the widths of different pads are equal. However, in the embodiments of the present disclosure, the widths of different pads 6 are designed differently, which can increase the flexibility of designing the widths of different pads 6.

For example, compared with the second pad 9, the first pad 8 can be designed to be wider, and then the first pad 8 can be divided into two areas, one is configured to overlap with the side trace 7, and the other one is not configured to overlap with the side trace 7. Furthermore, during the detection of the display panel, the probe of the test device can be placed in the area of the first pad 8 that is not configured to overlap with the side trace 7 when it is necessary to apply a signal to the first pad 8 or receive a signal on the first pad 8 through the test device.

When the above detection process is performed before the formation of the side traces 7, such as on the production line of the display panel, the probe can be prevented from contacting the area of the first pad 8 configured to overlap with the side trace 7, thereby preventing the area from being damaged. Therefore, after the side traces 7 are formed, the poor connection between the first pad 8 and the side trace 7 caused by scratches in the area can be avoided.

When the above detection process is performed after the formation of the side traces 7, for example, when the display panel is returned to the factory, the probe of the test device does not need to be placed on the side trace 7, which can avoid the probe from contacting the side trace 7, thereby preventing the probe from damaging the area where the side trace 7 overlaps with the first pad 8, and preventing problems with the stability of the connection between the side trace 7 and the first pad 8.

In some embodiments of the present disclosure, referring to FIG. 4 and FIG. 5, the first pad 8 includes a first edge 1a and a second edge 1b opposite to each other along the first direction x. Along the first direction x, a distance w1 between the first edge 1a and the side trace 7 overlapping with the first pad 8 is greater than a distance w2 between the second edge 1b and the side trace 7 overlapping with the first pad 8, and thus the area between the first edge 1a and the side trace 7 overlapping with the first pad 8 can be regarded as the area of the first pad 8 that does not overlap with the side trace 7 and is used to contact the probe.

The second pad 9 includes a third edge 1c and a fourth edge 1d opposite to each other along the first direction x. Along the first direction x, a distance w3 between the third edge 1c and the side trace 7 overlapping with the second pad 9 is equal to a distance w4 between the fourth edge 1d and the side trace 7 overlapping with the second pad 9.

Moreover, the above w2 and w3 can be equal or different. For example, w2=w3, or w2>w3.

In some embodiments of the present disclosure, the side traces 7 includes a first side trace 10 and a second side trace 13, the first side trace 10 is electrically connected to the second pad 9, and the second side trace 13 is electrically connected to the first pad 8.

In a design for achieving the difference in width between the first pad 8 and the second pad 9, the original width of the second pad 9 is kept unchanged, and only the width of the first pad 8 is increased. For example, some space can be released by reducing the spacing between the pads 6 and setting a gating circuit for the data lines to reduce the number of pads, in such a manner to widen the first pad 8. In this structure, since the width of the second pad 9 does not change, the maximum line width of the portion of the first side trace 10 located on the first surface 2 and the maximum line width of the portion of the second side trace 13 located on the first surface 2 can be consistent.

That is, referring to FIG. 4, in some embodiments of the present disclosure, the width h1 of the first pad 8 is greater than the width h2 of the second pad 9, and the width h1 of the first pad 8 is greater than the maximum line width q1 of the portion of the second side trace 13 located on the first surface 2. Furthermore, the maximum line width q1 of the portion of the second side trace 13 located on the first surface 2 is equal to the maximum line width q2 of the portion of the first side trace 10 located on the first surface 2.

In another design for achieving the difference in width between the first pad 8 and the second pad 9, the second pad 9 is designed to be narrower compared to the original width, and the space released after the second pad 9 is narrowed can be further used to widen the first pad 8, so that the first pad 8 has a larger width. In this structure, since the width of the second pad 9 is reduced, the maximum line width of the portion of the first side trace 10 located on the first surface 2 can be reduced accordingly, so that the line width of the first side trace 10 better matches the narrowed size of the second pad 9, thereby enabling the first side trace 10 to better overlap with the second pad 9.

That is, referring to FIG. 5, in some embodiments of the present disclosure, the width h1 of the first pad 8 is greater than the width h2 of the second pad 9, and the width h1 of the first pad 8 is greater than the maximum line width q1 of the portion of the second side trace 13 located on the first surface 2. Moreover, the maximum line width q1 of the portion of the second side trace 13 located on the first surface 2 is greater than the maximum line width q2 of the portion of the first side trace 10 located on the first surface 2.

In some embodiments of the present disclosure, referring to FIG. 1 to FIG. 3 again, the first pad 8 is further electrically connected to the signal line 5.

The side traces 7 includes the first side trace 10 electrically connected to the second pad 9.

The display panel includes at least one test unit 11, the test unit 11 includes two test groups 50, and each of the two test groups 50 includes one second pad 9 and one first side trace 10 electrically connected to each other. The two test groups 50 in the test unit 11 are connected to each other through a first connecting line 12. For example, in the test unit 11, the second pads 9 in the two test groups 50 are connected to each other through the first connecting line 12, or the first side traces 10 in the two test groups 50 are connected to each other through the first connecting line 12.

In some embodiment of the present disclosure, at least two types of detection are involved.

One of the detections is the detection of the signal lines 5. As mentioned above, on the production line of the display panel, or when the display panel is returned to the factory, the resistance and other parameters of the signal lines 5 can be detected to determine whether there is a short circuit or open circuit in the signal lines 5, and then to determine whether the display panel is defective. During the detection process, the probe of the test device applies a signal to the first pad 8, or receives a signal from the first pad 8.

The other one of the detections is the detection of the side traces 7. After forming the side traces 7, by detecting whether the first side trace 10 is well connected to the second pad 9, it can be estimated whether the second side trace 13 is well connected to the first pad 8, and thus it can be estimated whether the second side trace 13 can normally transmit signals to the signal line 5. Taking the first side traces 10 of the two test groups 50 forming a loop through the first connecting line 12 as an example, during the detection process, the test device provides a detection voltage to the second pad 9 in one of the test groups 50, and detects the signal of the second pad 9 in the other one of the test groups 50 to determine whether the first side trace 10 is stably connected to the second pad 9. If it is determined that the connection between the first side trace 10 and the second pad 9 is good, then it can be estimated that the connection between the second side trace 13 and the first pad 8 is also good. If it is determined that the connection between the first side trace 10 and the second pad 9 is poor, it can be estimated that the connection between the second side trace 13 and the first pad 8 is also poor.

The detection of the side traces 7 can also be performed on the production line of the display panel or when the display panel is returned to the factory. For example, on the production line of the display panel, after forming the side traces 7, the connection of the side traces 7 can be detected. After the display panel leaves the factory, it may be returned to the factory based on customer feedback, and the connection of the side traces 7 can also be retested when the display panel is returned to the factory.

In summary, the first pad 8 is used for display, while the second pad 9 is not used for display and is only used for testing the connection of the side traces 7. After the display panel is put into use, the second pad 9 is not used to transmit the display signal.

In other words, in the embodiments of the present disclosure, the pads 6 used for display are set as the first pads 8, so that these pads 6 have a larger width, and thus an area that does not overlap with the second side trace 13 can be divided in each of the first pads 8. Therefore, when the signal lines 5 are detected, the probe of the test device can be directly placed in this area, thereby preventing the area of the first pad 8 that overlaps with the second side trace 13 from being scratched.

The pads 6 used only for testing are set as the second pads 9, so that these pads 6 have a smaller width, and these pads 6 are not connected to the signal lines 5. When the signal lines 5 are detected, the probe of the test device is not placed on these pads 6, and even if these pads 6 have a smaller width, there is no risk of being scratched by the probe during the detection process. Moreover, even if the first pads 8 are widened by releasing space after these second pads 9 are narrowed, there is no adverse effect on the display.

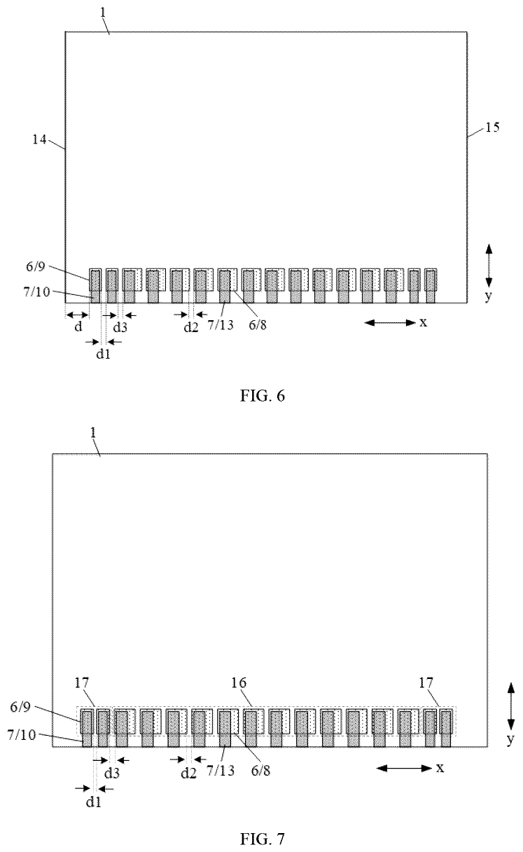

In some embodiments of the present disclosure, as shown in FIG. 6, which is a top view of another display panel according to some embodiments of the present disclosure, the substrate 1 includes a first edge 14 extending along a second direction y, at least part of the second pads 9 are located between the first edge 14 and the first pads 8, and the second direction y intersects with the first direction x.

In the manufacturing process of the display panel, it is also necessary to perform edge grinding treatment on the substrate 1 to remove defects and burrs on the edges of the substrate 1, as well as adjust the shape and size of the edges of the substrate 1.

Compared with the second pad 9, the first pad 8 is responsible for the display function, so it is more important. In some embodiments of the present disclosure, the distance between the first pads 8 and the first edge 14 can be increased by spacing at least part of the second pads 9 between the first pads 8 and the first edge 14 of the substrate 1. In this way, when performing edge grinding treatment on the first edge 14, the tool used for the edge grinding operation is difficult to contact the first pads 8, thereby reducing the possibility of scratching the first pad 8 during the edge grinding treatment from a spatial perspective, and preventing the first pads 8 from being damaged and affecting the display effect.

In some embodiments of the present disclosure, referring to FIG. 6, a distance d between the first edge 14 and the second pad 9 adjacent thereto is greater than a distance between two adjacent pads 6 along the first direction x.

“A distance between two adjacent pads 6 along the first direction x” includes: a distance d1 between two adjacent second pads 9 along the first direction x, a distance d2 between two adjacent first pads 8 along the first direction x, and the distance d3 between a first pad 8 and a second pad 9 adjacent to each other along the first direction x.

That is, d>d1, d>d2, d>d3.

When at least part of the second pads 9 are spaced between the first pads 8 and the first edge 14, setting the distance between the first edge 14 and the second pad 9 to be greater than the distance between two adjacent pads 6 can also reduce the possibility of scratching the second pad 9 during the edge grinding treatment, thereby preventing the second pad 9 from being damaged and affecting the detection of the side traces 7.

For example, when the edge grinding treatment of the first edge 14 is performed before the side traces 7 are formed, if the second pad 9 is scratched during the edge grinding process, there is a possibility of poor connection between the second pad 9 and the first side trace 10 when the side traces 7 are subsequently formed. However, this poor connection is caused by the damage of the second pad 9, not by the misalignment of the side traces 7 or other reasons. When the side traces 7 are subsequently tested, if it is detected that the first side trace 10 is abnormally connected, misjudgment may easily occur.

When the edge grinding treatment of the first edge 14 is performed after the side traces 7 are formed, if the second pad 9 is scratched during the edge grinding process, there may be a poor connection between the second pad 9 and the first side trace 10 due to the scratches. Therefore, when the display panel is returned to the factory and the side traces 7 need to be retested, misjudgment may also easily occur.

By increasing the distance between the second pad 9 and the first edge 14, the above situation can be effectively avoided.

In some embodiments of the present disclosure, the distance between the first edge 14 and the second pad 9 adjacent thereto is d, and 600 μm≤d≤700 μm. Within this distance range, when performing edge grinding treatment on the first edge 14, the tool used for the edge grinding operation is more difficult to touch the second pad 9, which can prevent the second pad 9 from being scratched during the edge grinding treatment to a greater extent.

Furthermore, referring to FIG. 6, the substrate 1 further includes a second edge 15, the second edge 15 extends along the second direction y, and is opposite to the first edge 14 along the first direction x. Part of the second pads 9 are located between the first pads 8 and the second edge 15.

For example, the display panel includes two test units 11, one is located between the first edge 14 and the first pad 8, and the other one is located between the second edge 15 and the first pad 8.

The distance between the second edge 15 and the second pad 9 adjacent thereto is equal to the distance between the first edge 14 and the second pad 9 adjacent thereto. For example, the distance between the second edge 15 and the second pad 9 adjacent thereto is also greater than or equal to 600 μm and less than or equal to 700 μm, thereby preventing the second pad 9 close to the second edge 15 from being scratched when performing edge grinding treatment on the second edge 15.

In some embodiments of the present disclosure, as shown in FIG. 7, which is a top view of another display panel according to some embodiments of the present disclosure, the display panel includes a first area 16 and a second area 17, the first pads 8 are located in the first area 16, and the second pads 9 are located in the second area 17. The first area 16 and the second area 17 are arranged along the first direction x. For example, the display panel includes one first area 16 and two second areas 17, and the first area 16 is located between the two second areas 17.

The distance d1 between two adjacent second pads 9 in the second area 17 is less than the distance d2 between two adjacent first pads 8 in the first area 16, and/or, the distance d1 between two adjacent second pads 9 in the second area 17 is less than the distance d3 between the first pad 8 and the second pad 9 adjacent to each other.

In the above setting method, the distance between adjacent second pads 9 is further reduced, thereby further releasing some space in the first direction x, which can be used to widen the first pad 8 to a greater extent, thereby preventing the probe from damaging the area of the first pad 8 overlapping with the second side trace 13 when detecting the signal lines 5. Alternatively, this space can be used to increase the distance between the second pad 9 and the first edge 14 or the second edge 15, thereby preventing the second pad 9 from being scratched during the edge grinding treatment to a greater extent.

In addition, in some embodiments of the present disclosure, the distance between the second pad 9 and the first edge 14 or the second edge 15 can be further increased by narrowing the second pad 9. For example, the width of the second pad 9 can be reduced to be less than or equal to half the width of the first pad 8 along the first direction x.

Furthermore, the distance between two adjacent second pads 9 in the second area 17 is d1, and 20 μm≤d1≤70 μm. The distance between two adjacent first pads 8 in the first area 16 is d2, and 50 μm≤d2≤80 μm. The distance between the first pad 8 and the second pad 9 adjacent to each other is d3, and 50 μm≤d3≤80 μm.

For example, d1=30 μm, d2=70 μm, d3=70 μm. Alternatively, d1=50 μm, d2=70 μm, d3=70 μm.

The above range of d1 covers the process error. On the premise of ensuring that d1 is small, the short circuit between two second pads 9 caused by reasons such as process accuracy can also be prevented.

As mentioned above, the present disclosure relates to the test of the side traces. When testing the connection of the side traces, the following method is usually used in the related art.

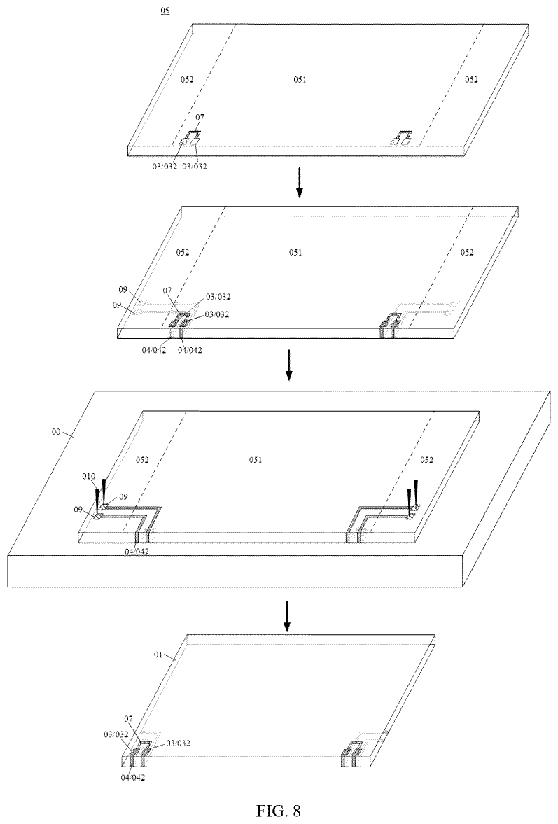

As shown in FIG. 8, which is a schematic diagram of a display panel according to the related art in a manufacturing process, in the manufacturing process of the display panel, a substrate 05 to be cut is first formed, and the substrate 05 to be cut includes a panel area 051 and a cutting area 052. The panel area 051 includes pads 03, and the pads 03 include test pads 032. The panel area 051 further includes a connecting line 07. The connecting line 07 and the pads 03 are located on the same side of the substrate 05 to be cut, and two test pads 032 are connected through the connecting line 07.

Side traces 04 are then formed, which include test side traces 042 electrically connected to the test pads 032. The test side traces 042 corresponding to two test pads 032 are respectively connected to a test pin 09 on the back surface of the substrate 05 to be cut. That is, the test pins 09 and the connecting line 07 are located on different surfaces of the substrate 05 to be cut.

The side traces 04 are then detected. During the detection process, the substrate 05 to be cut is turned over and placed in a test device 00, with the back surface of the substrate 05 to be cut facing upward. Probes 010 of the test device 00 are placed on the test pins 09, by applying a detection voltage to one of the test pins 09 and detecting the electrical signal on the other one of the test pins 09, it is determined whether the connection between the test side traces 042 and the test pads 032 is good.

Finally, the cutting area 052 is cut off to form a display panel.

In this way, two test pads 032 form a loop through the connecting line 07 on the front surface, and when the side traces 04 are detected, the probes of the test device 00 need to be placed on the test pins 09 on the back surface of the substrate 05 to be cut, and then the substrate 05 to be cut needs to be turned over when placed in the test device 00. In this way, the probes 010 of the test device 00 can be placed on the test pins 09. However, after being turned over, the front surface of the substrate 05 to be cut faces downward, which can easily cause the signal lines on the front surface to be scratched, thereby affecting the yield of the display panel.

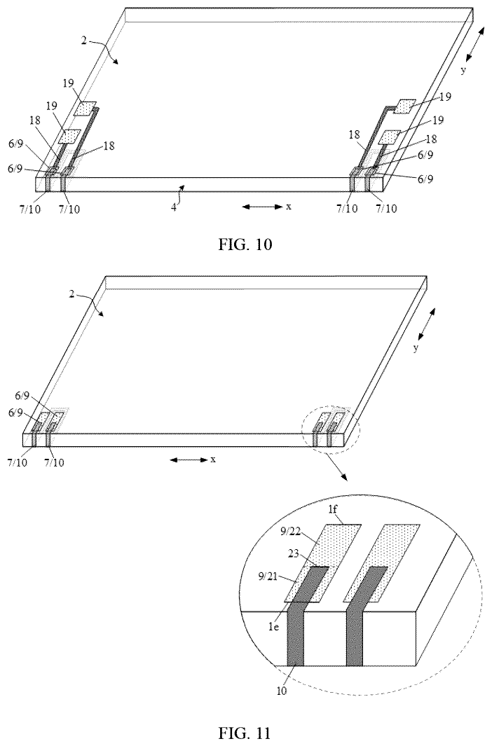

In this regard, in some embodiments of the present disclosure, as shown in FIG. 1 to FIG. 3, FIG. 10 and FIG. 11, in the test unit 11, the first side traces 10 in the two test groups 50 are connected to each other through the first connecting line 12, and the first connecting line 12 is located on the second surface 3.

That is, in some embodiments of the present disclosure, two first side traces 10 in the two test groups 50 form a loop on the back surface of the substrate 1, so that when the side traces 7 are detected, the probes of the test device can be directly placed on the second pads 9 on the front surface of the substrate 1, or test pins are formed on the front surface of the substrate 1, and the probes are directly placed on the test pins on the front surface. In this way, when the substrate 1 is placed in the test device, it can still be kept with its front surface facing upward without being turned over, thereby preventing the signal lines 5 on the front surface of the substrate 1 from being damaged.

Regarding the above structure “the first side traces 10 in the two test groups 50 are connected to each other through the first connecting line 12, and the first connecting line 12 is located on the second surface 3”, in some embodiments of the present disclosure, referring to FIG. 1 to FIG. 3, the display panel further includes a test trace 18 located on the first surface 2, the test trace 18 is electrically connected to the second pad 9, and the edge of the test trace 18 is flush with the edge of the substrate 1.

For example, when at least one test unit 11 is located between the first edge 14 and the first pad 8, the test trace 18 connected to the test unit 11 can be flush with the first edge 14. When at least one test unit 11 is located between the second edge 15 and the first pad 8, the test trace 18 connected to the test unit 11 can be flush with the second edge 15.

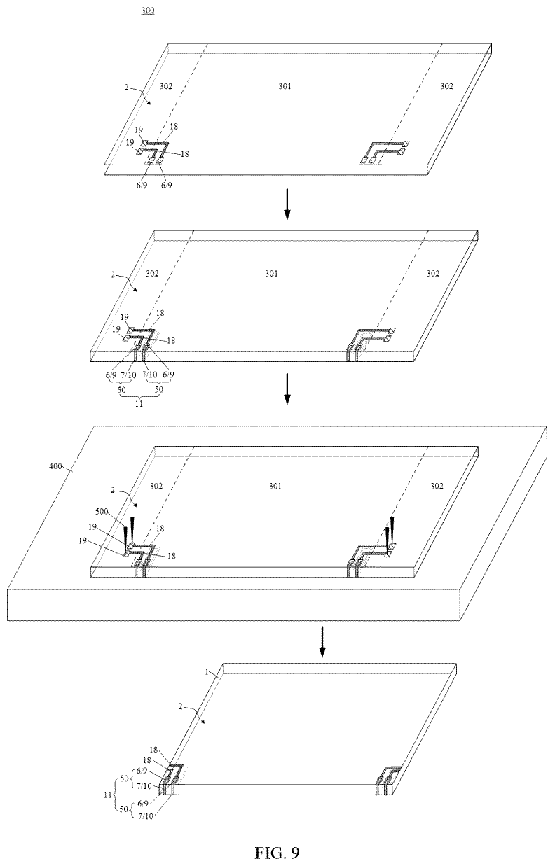

Based on this structure, as shown in FIG. 9, which is a schematic diagram of a display panel in a manufacturing process according to some embodiments of the present disclosure, in the manufacturing process of the display panel, a substrate 300 to be cut is first formed. The substrate 300 to be cut includes a panel area 301 and a cutting area 302, the pads 6 and the signal lines 5 are located in the panel area 301, and the cutting area 302 includes a test pin 19, the test pin 19 is electrically connected to the second pad 9 through the test trace 18, and the test pin 19 and the test trace 18 are located on the same side as the second pad 9.

Side traces 7 are then formed, and the first side traces 10 in the test unit 11 are connected through the first connecting line 12 located on the second surface 3.

The side traces 7 are then detected. The probe 500 of the first test device 400 contacts the test pin 19, by applying a detection voltage to the second pad 9 or detecting a signal of the second pad 9 through the test pin 19, the connection between the first side trace 10 and the second pad 9 is determined.

Finally, the substrate 300 to be cut is cut off, and the cutting area 302 is removed to form a display panel.

Based on this structure, the edge grinding treatment of the first edge 14 and the second edge 15 mentioned above can be performed when the cutting area 302 is removed. That is, the edge grinding treatment of the first edge 14 and the second edge 15 is performed after the side traces 7 are formed.

With this structure, when the side traces 7 are detected, the substrate 1 does not need to be turned over when placed in the first test device 400. The first surface 2 of the substrate 1 faces upward, and the probe 500 of the first test device 400 is directly placed on the test pin 19 on the first surface 2 to complete the test. After the detection is completed, the test pin 19 is cut off and removed without occupying space in the display panel. Moreover, since the test pin 19 is not retained in the final panel structure, there is no need to consider the problem of the test pin 19 occupying the panel space. Therefore, the size and spacing design of the test pin 19 can also be more flexible. For example, the area of the test pin 19 can be larger than the area of the second pad 9 to improve the alignment accuracy of the probe and the test pin 19.

In addition, during the above detection process, the probe 500 of the first test device 400 is placed on the test pin 19, rather than directly placed on the second pad 9 and the first side trace 10, so that the second pad 9 and the first side trace 10 are not damaged. In this way, when the display panel is returned to the factory and the side traces 7 need to be retested, the accuracy of the retest is not affected. It should be noted that when the display panel is returned to the factory for retesting, the test pin 19 has been cut off, so the probe 500 of the first test device 400 may be directly placed on the first side trace 10 above the second pad 9.

Regarding the structure “the first side traces 10 in the two test groups 50 are connected to each other through the first connecting line 12, and the first connecting line 12 is located on the second surface 3”, in some embodiments of the present disclosure, as shown in FIG. 10, which is a structural schematic diagram of another display panel according to some embodiments of the present disclosure, the display panel further includes a test trace 18 and a test pin 19, the test trace 18 and the test pin 19 are located on the first surface 2, and the test pin 19 is electrically connected to the second pad 9 through the test trace 18. That is, in this structure, the test pin 19 is retained in the final panel structure.

Based on this structure, the edge grinding treatment on the first edge 14 and the second edge 15 mentioned above can be performed before or after the side traces 7 are formed.

With this structure, when the connection of the side traces 7 is detected, the substrate 1 does not need to be turned over when it is placed in the first test device, the first surface 2 of the substrate 1 faces upward, and the probe of the first test device is directly placed on the test pin 19 on the first surface 2 to complete the test. Moreover, in this structure, the test pin 19 is retained in the final panel structure. When the display panel is returned to the factory and the side traces 7 need to be retested, the probe of the first test device can still be placed on the test pin 19, without being placed on the second pad 9.

In some embodiments of the present disclosure, referring to FIG. 10 again, the test pin 19 does not overlap the second pad 9 connected thereto along the first direction x. That is, the test pin 19 and the second pad 9 connected thereto are not arranged along the first direction x, so that the test pin 19 can be prevented from occupying the arrangement space of the first pad 8 and the second pad 9 in the first direction x.

In some embodiments of the present disclosure, in order to improve the alignment accuracy of the probe and the test pin 19 during testing, referring to FIG. 10, the area of the test pin 19 can be set to be larger than the area of the second pad 9; and/or, the distance between two test pins 19 can be set to be greater than the distance between two second pads 9 connected thereto.

Regarding the structure “the first side traces 10 in the two test groups 50 are connected to each other through the first connecting line 12, and the first connecting line 12 is located on the second surface 3”, in some embodiments of the present disclosure, as shown in FIG. 11, which is a structural schematic diagram of another display panel according to some embodiments of the present disclosure, the second pad 9 includes a first region 21 and a second region 22 arranged along the second direction y, and the second direction y intersects with the first direction x.

The portion of the first side trace 10 located on the first surface 2 overlaps with the first region 21 and does not overlap with the second region 22. That is, in the direction perpendicular to the plane of the substrate 1, the portion of the first side trace 10 located on the first surface 2 overlaps with the first region 21 and does not overlap with the second region 22.

For example, referring to FIG. 11, the portion of the first side trace 10 located on the first surface 2 includes a first trace edge 23. The first trace edge 23 extends along the first direction x, and overlaps with the second pad 9 in the direction perpendicular to the plane of the substrate 1.

The second pad 9 includes a fifth edge 1e and a sixth edge 1f opposite to each other in the second direction y. In some embodiments of the present disclosure, the first trace edge 23 of the first side trace 10 can be used as the boundary between the first region 21 and the second region 22 in the second pad 9. That is, the area between the fifth edge 1e of the second pad 9 and the first trace edge 23 of the first side trace 10 is defined as the first region 21 of the second pad 9, and the area between the sixth edge 1f of the second pad 9 and the first trace edge 23 of the first side trace 10 is defined as the second region 22 of the second pad 9.

Based on this structure, the edge grinding treatment on the first edge 14 and the second edge 15 mentioned above can be performed before or after the side traces 7 are formed.

In this structure, the size of the second pad 9 is elongated along the second direction y, thereby dividing an area that does not overlap with the first side trace 10 and is used for contacting the probe. In this structure, when the side traces 7 are detected, the substrate 1 does not need to be turned over when it is placed in the first test device. Moreover, the probe of the first test device can be directly placed in the second region 22 of the second pad 9 to complete the test, without damaging the area of the second pad 9 for overlapping with the first side trace 10. Therefore, when the display panel is returned to the factory and the side traces 7 need to be retested, there will be no misjudgment. In addition, in this structure, there is no need to provide the test pin 19 and the test trace 18, and the panel structure is more simplified.

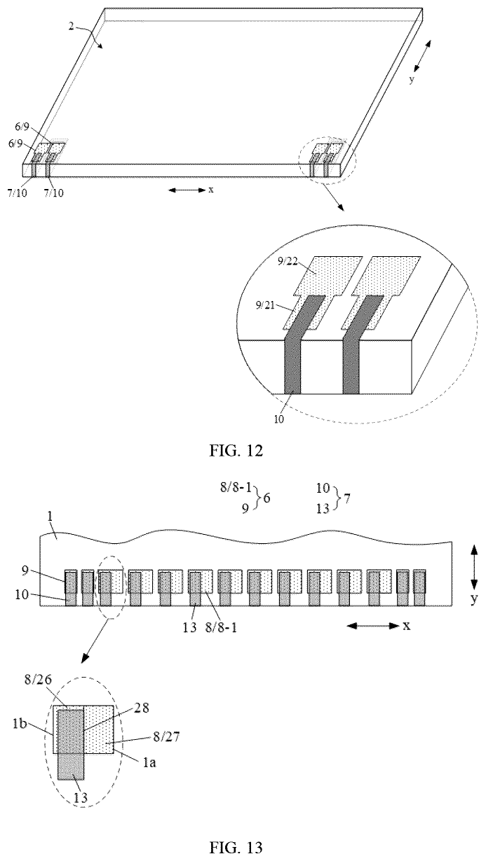

Furthermore, as shown in FIG. 12, which is a structural schematic diagram of another display panel according to some embodiments of the present disclosure, in order to improve the alignment accuracy between the probe and the second region 22, the width of the second region 22 can be greater than the width of the first region 21 along the first direction x.

In some embodiments of the present disclosure, as shown in FIG. 13, which is a structural schematic diagram of another display panel according to some embodiments of the present disclosure, the first pad 8 includes a first sub-pad 8-1, and the first sub-pad 8-1 includes a third region 26 and a fourth region 27 arranged along the first direction x.

The side traces 7 include the second side trace 13 electrically connected to the first pad 8. In the second side trace 13 electrically connected to the first sub-pad 8-1, the portion of the second side trace 13 located on the first surface 2 overlaps with the third region 26 and does not overlap with the fourth region 27. That is, the portion of the second side trace 13 located on the first surface 2 overlaps with the third region 26 and does not overlap with the fourth region 27 in the direction perpendicular to the plane of the substrate 1.

The third region 26 is the area of the first pad 8 described above for overlapping with the second side trace 13, and the fourth region 27 is the area of the first pad 8 described above that does not overlap with the second side trace 13.

For example, referring to FIG. 13, the portion of the second side trace 13 located on the first surface 2 includes a second trace edge 28. The second trace edge 28 extends along the second direction y, and overlaps with the first pad 8 in the direction perpendicular to the plane of the substrate 1.

The first pad 8 includes the first edge 1a and the second edge 1b opposite to each other in the first direction x. In some embodiments of the present disclosure, the second trace edge 28 of the second side trace 13 can serve as the boundary between the third region 26 and the fourth region 27 in the first pad 8. That is, the area between the first edge 1a of the first pad 8 and the second trace edge 28 of the second side trace 13 is the fourth region 27 in the first pad 8, and the area between the second edge 1b of the first pad 8 and the second trace edge 28 is the third region 26 in the first pad 8.

In the above structure, the first pad 8 includes the fourth region 27 that does not overlap with the second side trace 13. When the signal lines 5 are detected, the fourth region 27 can be used to contact the probe of the test device. Regardless of whether the detection process is performed before or after the side traces 7 are formed, the probe of the test device can be directly placed in the fourth region 27 of the first pad 8, thereby avoiding scratches at the overlap position of the first pad 8 and the second side trace 13, and avoiding the display being affected by the poor connection between the first pad 8 and the second side trace 13.

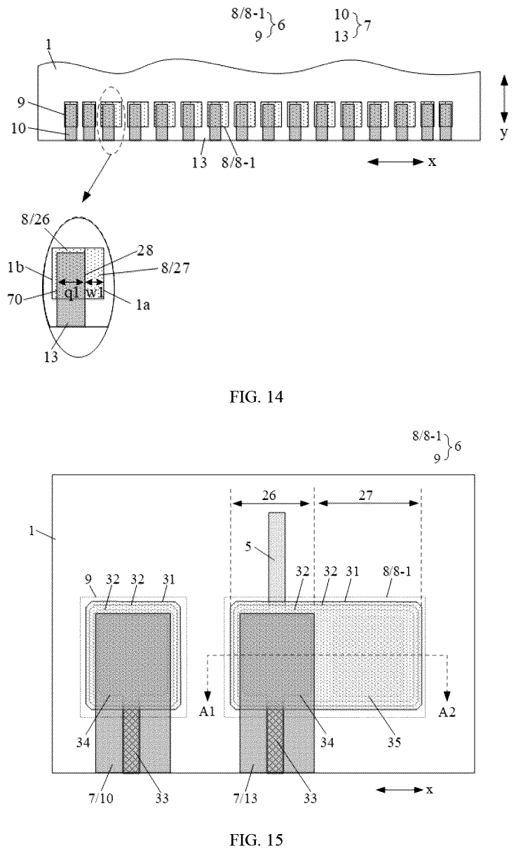

In some embodiments of the present disclosure, as shown in FIG. 14, which is a structural schematic diagram of another display panel according to some embodiments of the present disclosure, along the first direction x, the width w1 of the fourth region 27 is less than the maximum line width q1 of the portion of the second side trace 13 located on the first surface 2. That is, along the first direction x, the distance w1 between the first edge 1a and the second trace edge 28 is less than the maximum line width q1 of the portion of the second side trace 13 located on the first surface 2. Alternatively, the above can be described as follows: along the first direction x, the distance w1 between the first edge 1a and the second side trace 13 overlapping with the first sub-pad 8-1 is less than the maximum line width q1 of the portion of the second side trace 13 located on the first surface 2.

Since the fourth region 27 is only used for contacting the probe, the width of the fourth region 27 can be designed to be smaller. Under the condition that the display panel has a constant size along the first direction x, more pads 6 can be arranged, or the parameters such as the spacing between the pads 6 can be designed more flexibly.

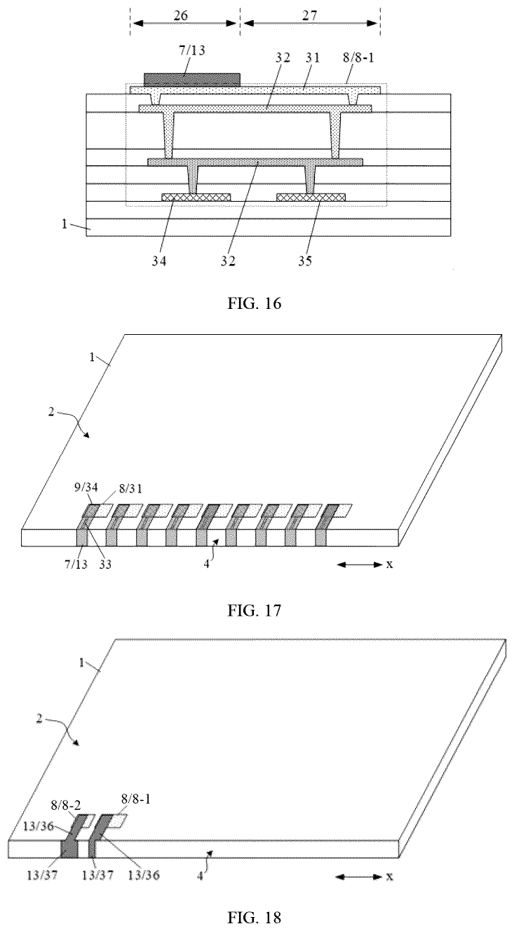

In some embodiments of the present disclosure, as shown in FIG. 15 and FIG. 16, where FIG. 15 is a structural schematic diagram of a pad 6 according to some embodiments of the present disclosure, and FIG. 16 is a structural schematic diagram of a film layer of a display panel according to some embodiments of the present disclosure, the pad 6 includes a first metal portion 31 and a second metal portion 32. The first metal portion 31 overlaps with the second side trace 13, and the second metal portion 32 is located on the side of the first metal portion 31 close to the substrate 1.

In the first sub-pad 8-1, the second metal portion 32 is located in the third region 26 and the fourth region 27. That is, along the first direction x, the width of the second metal portion 32 is greater than the maximum line width of the portion of the second side trace 13 located on the first surface 2.

In some embodiments of the present disclosure, the pad 6 may include a plurality of metal portions arranged in a stacked manner.

The first metal portion 31 is the top metal portion of the pad 6, and when the side trace 7 overlap with the pad 6, it means that the side trace 7 is in contact with the first metal portion 31. For the first sub-pad 8-1, when the first sub-pad 8-1 includes the third region 26 and the fourth region 27, it means that the first metal portion 31 in the first sub-pad 8-1 is located in the third region 26 and the fourth region 27, that is, the width of the first metal portion 31 is greater than the maximum line width of the portion of the second side trace 13 located on the first surface 2 along the first direction x.

The second metal portion 32 is located on the side of the first metal portion 31 close to the substrate 1. In the first sub-pad 8-1, by setting the second metal portion 32 to also have a larger width, it is helpful to reduce the overall load of the first sub-pad 8-1.

It should be noted that in some embodiments of the present disclosure, when the pad 6 can include a plurality of metal portions arranged in a stacked manner, the width of the pad 6 can be limited by the width of the first metal portion 31 at the top, which is used to overlap with the side trace 7. That is, the width of the pad 6 in the first direction x is the width of the first metal portion 31 in the first direction x. For example, for the first pad 8, the first edge 1a and the second edge 1b of the first pad 8 shown in FIG. 14 can be understood as two edges of the first metal portion 31 in the first pad 8. The width of the first pad 8 in the first direction x is the distance between the first edge 1a and the second edge 1b, and is also the width of the first metal portion 31 in the first direction x.

In some embodiments of the present disclosure, as shown in FIG. 15 and FIG. 17, where FIG. 17 is a structural schematic diagram of another display panel according to some embodiments of the present disclosure, the display panel further includes a first trace 33 located on the first surface 2. The first trace 33 is electrically connected to the first pad 8, and is located on the side of the first pad 8 close to the first side face 4, and the edge of the first trace 33 is flush with the edge of the first side face 4.

The side traces 7 include the second side trace 13 electrically connected to the first pad 8, and the portion of the second side trace 13 located on the first surface 2 overlaps with the first trace 33 in the direction perpendicular to the plane of the substrate 1.

There are at least two understandings regarding the first trace 33 mentioned above.

The first is that in the conventional display panel, the circuit board may be bound in a front-side manner. That is, the circuit board is bound to the first surface 2 of the substrate 1, and the circuit board is located at the lower border of the display panel. In this type of display panel, the pad 6 leads out the binding trace downward in the direction away from the signal lines 5, and the binding trace extends to the binding area and is electrically connected to the binding pin configured to bind the circuit board.

In some embodiments of the present disclosure, the circuit board is bound in a back-side manner. That is, the circuit board is bound to the second surface 3 of the substrate 1, which is the back surface of the substrate 1. In this way, the lower border can be narrowed to achieve a narrow border design.

In some embodiments of the present disclosure, the display panel under the back-side binding design can still use the structure of the display panel under the front-side binding design, where only the binding pin in the display panel under the front-side binding design is cut off, and the binding area is removed, and then the side traces 7 are formed. The first trace 33 can be understood as the part of the binding trace that is finally retained in the display panel.

The second is that the first trace 33 can also be used for electrostatic protection. In a structure, the pad 6 leads out the electrostatic protection trace downward in the direction away from the signal line 5, and electrostatic protection traces connected to a plurality of pads 6 are connected to a protection bus. The protection bus is located outside the cutting line of the display panel and is used to provide electrostatic protection for the display panel in the manufacturing process. When the display panel is subsequently cut, the protection bus is cut off. The first trace 33 can also be understood as the part of the electrostatic protection trace that is finally retained in the panel structure.

When the edge of the first trace 33 is flush with the edge of the first side face 4, the end of the first trace 33 is exposed at the edge of the first side face 4. By setting the portion of the second side trace 13 located on the first surface 2 to overlap with the first trace 33, the second side trace 13 can contact the exposed end of the first trace 33 when extending on the first side face 4, thereby strengthening the connection between the second side trace 13 and the second pad 9.

Referring to FIG. 15 and FIG. 16, the pad 6 further includes a third metal portion 34. The third metal portion 34 is located on the side of the first metal portion 31 close to the substrate 1 and connected to the first trace 33, and the third metal portion is arranged on the same layer as the first trace 33.

In the first sub-pad 8-1, the pad 6 can further include a fourth metal portion 35. The fourth metal portion 35 is at least located in the fourth region 27, and arranged on the same layer as the third metal portion 34. The fourth metal portion 35 is provided on a side of the third metal portion 34, and can be used to improve the film layer flatness of the second metal portion 32 and the first metal portion 31, thereby improving the overlap performance with the second side trace 13.

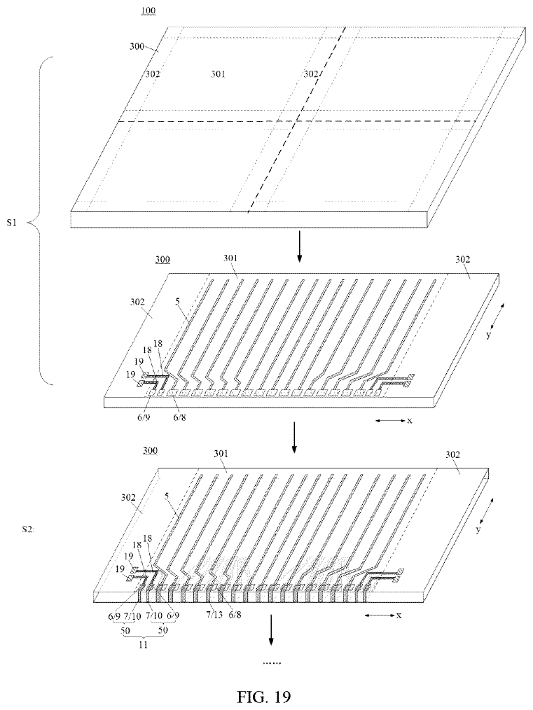

In some embodiments of the present disclosure, as shown in FIG. 18, which is a structural schematic diagram of another display panel according to some embodiments of the present disclosure, the first pads 8 include the first sub-pad 8-1 and a second sub-pad 8-2, and the width of the first sub-pad 8-1 is greater than the width of the second sub-pad 8-2 along the first direction x.

For example, each of the first sub-pad 8-1 and the second sub-pad 8-2 includes the third region 26 and the fourth region 27. However, the width of the fourth region 27 in the first sub-pad 8-1 is greater than the width of the fourth region 27 in the second sub-pad 8-2 along the first direction x.

The above structure can design the width of different first pads 8 more flexibly. For example, the more important part (first sub-pads 8-1) of the first pads 8 can be designed to be wider, so that there is a larger area for contacting the probe, the alignment accuracy with the probe is improved, thereby prevent the area of these first pads 8 (first sub-pads 8-1) used for overlapping with the second side trace 13 from being damaged.

Furthermore, referring to FIG. 18, the side traces 7 include the second side trace 13 electrically connected to the first pad 8, and the second side trace 13 includes a first line segment 36 at least located on the first surface 2 and a second line segment 37 at least located on the first side face 4.

In the second side trace 13 electrically connected to the first sub-pad 8-1, the width of the first line segment 36 is greater than the width of the second line segment 37 along the first direction x. In the second side trace 13 electrically connected to the second sub-pad 8-2, the width of the first line segment 36 is less than the width of the second line segment 37 along the first direction x.

The width of the second sub-pad 8-2 is relatively small, so that the first line segment 36 in the second side trace 13 overlapping with the second sub-pad 8-2 can be designed to be narrower, thereby freeing up a larger area for contacting the probe, and preventing the probe from placing in the area of the second sub-pad 8-2 that overlaps with the second side trace 13 due to misalignment.

Furthermore, the width of the first line segment 36 and the second line segment 37 in the second side trace 13 electrically connected to each of the first sub-pad 8-1 and the second sub-pad 8-2 is designed as above, and the load uniformity of the second side traces 13 electrically connected to the first sub-pad 8-1 and the second sub-pad 8-2 can also be balanced.

In some embodiments of the present disclosure, as shown in FIG. 15, the width of the second pad 9 is less than or equal to half of the width of the first pad 8 along the first direction x, so as to reasonably distribute the width of the second pad 9 and the first pad 8, and ensure that the first pad 8 has enough area that does not overlap with the second side trace 13 for contacting the probe.

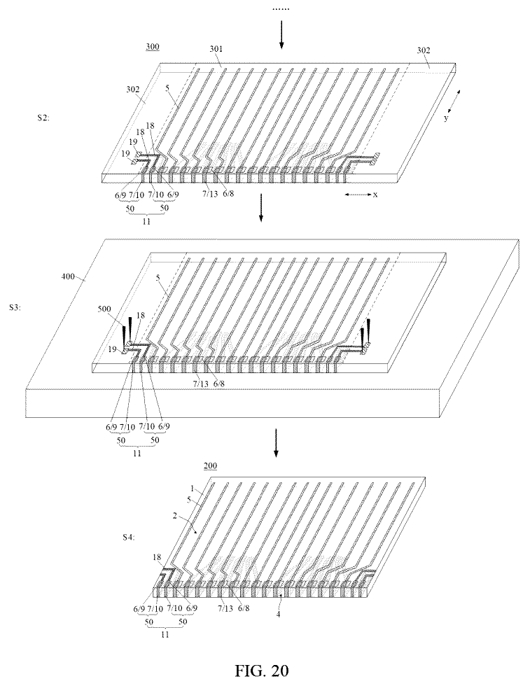

Based on the same inventive concept, an embodiment of the present disclosure provides a method for manufacturing a display panel, in conjunction with FIG. 1 to FIG. 3, as shown in FIG. 19 and FIG. 20, where FIG. 19 is a partial schematic diagram of a method for manufacturing a display panel according to some embodiments of the present disclosure, and FIG. 20 is a partial schematic diagram of another method for manufacturing a display panel according to some embodiments of the present disclosure, the manufacturing method includes cutting a motherboard 100 to form a display panel 200.

The display panel 200 includes a substrate 1, and the substrate 1 includes a first surface 2 and a second surface 3 opposite to each other, and a first side face 4 located between the first surface 2 and the second surface 3.

The display panel 200 further includes a plurality of signal lines 5 and a plurality of pads 6 located on the first surface 2. The pads 6 are located on a side of the signal lines 5 close to the first side face 4, and at least part of the pads 6 are electrically connected to the signal lines 5. The pads 6 include a first pad 8 and a second pad 9 arranged along a first direction x, and the width of the second pad 9 is less than the width of the first pad 8 along the first direction x.

The display panel 200 further includes a plurality of side traces 7 arranged on the first surface 2, the first side face 4, and the second surface 3, and the side traces 7 are electrically connected to the pads 6.

In the related art, the widths of the plurality of pads 6 are uniformly designed. That is, the widths of different pads 6 are equal. However, in some embodiments of the present disclosure, the widths of different pads 6 are designed differently, which can increase the flexibility of designing the widths of different pads 6. For example, compared with the second pad 9, the first pad 8 can be designed to be wider, and then two areas are divided in the first pad 8, one is used to overlap with the side trace 7, and the other one does not overlap with the side trace 7. The area that does not overlap with the side trace 7 can be used to contact the probe of the external detection device during the testing, so as to avoid the first pad 8 from being scratched and affecting the binding stability with the side trace 7.

In some embodiments of the present disclosure, as shown in FIG. 1 to FIG. 3, FIG. 9, FIG. 19 and FIG. 20, the first pad 8 is further electrically connected to the signal line 5.

The side traces 7 includes a first side trace 10 electrically connected to the second pad 9.

The display panel 200 includes at least one test unit 11, the test unit 11 includes two test groups 50, and each of the two test groups 50 includes one second pad 9 and one first side trace 10 electrically connected to each other. The first side traces 10 of the two test groups 50 in the test unit 11 are connected to each other through the first connecting line 12, and the first connecting line 12 is located on the second surface 3.

After forming the side traces 7, the process of cutting the motherboard 100 to form the display panel 200 further includes: applying a detection voltage to one second pad 9 in the test unit 11a by a probe 500 of a first test device 400, and determining a connection between the first side trace 10 and the second pad 9 by detecting a signal of the other one second pad 9 in the test unit 11.

In some embodiments of the present disclosure, two first side traces 10 in the two test groups 50 form a loop on the back surface of the substrate 1, so that when the side traces 7 are detected, the probe of the test device can be directly placed on the second pad 9 on the front surface of the substrate 1. Alternatively, the test pin is formed on the front surface of the substrate 1, and the probe is directly placed on the test pin on the front surface. In this way, when the substrate 1 is placed in the test device, it can be kept with its front surface facing upward without being turned over, thereby preventing the signal lines 5 on the front surface of the substrate 1 from being damaged.

Furthermore, referring to FIG. 19 and FIG. 20, the process of cutting the motherboard 100 to form the display panel 200 includes the following steps.

Step S1: the motherboard 100 is cut to form the substrate 300 to be cut. The substrate 300 to be cut includes a panel area 301 and a cutting area 302. The pads 6 and the signal lines 5 are located in the panel area 301, and the cutting area 302 includes the test pin 19. The test pin 19 is electrically connected to the second pad 9 through the test trace 18, and the test pin 19 and the test trace 18 are located on the same side as the second pad 9.

Step S2: the side traces 7 are formed on the substrate 300 to be cut.

Step S3: the probe 500 of the first test device 400 contacts the test pin 19, the detection voltage is applied to the second pad 9 or detects the signal of the second pad 9 through the test pin 19, and the connection between the first side trace 10 and the second pad 9 is determined.

Step S4: the substrate 300 to be cut is cut, and the cutting area 302 is removed to form the display panel 200.

In the above process, when the side traces 7 are detected, the substrate 1 does not need to be turned over when it is placed in the first test device 400 with the first surface 2 of the substrate 1 facing upward, and the probe 500 of the first test device 400 is directly placed on the test pin 19 on the first surface 2 to complete the test. After the test is completed, the test pin 19 is cut off and removed without occupying space in the display panel. Moreover, since the test pin 19 is not retained in the final panel structure, it is not necessary to consider the problem of the test pin 19 occupying the panel space. Therefore, the size and spacing design of the test pin 19 is more flexible. For example, the area of the test pin 19 can be larger than the area of the second pad 9 to improve the alignment accuracy of the probe and the test pin 19.

In addition, during the above detection process, the probe 500 of the first test device 400 is placed on the test pin 19, rather than directly placed on the second pad 9 and the first side trace 10, so that the second pad 9 and the first side trace 10 cannot be damaged. In this way, when the display panel is returned to the factory and the side traces 7 need to be retested, the accuracy of the retesting is not affected. It should be noted that when the display panel is returned to the factory for retesting, the test pin 19 has been cut off, the probe 500 of the first test device 400 can be directly placed on the first side trace 10 above the second pad 9.

In some embodiments of the present disclosure, as shown in FIG. 13 and FIG. 14, the first pad 8 includes a first sub-pad 8-1, and the first sub-pad 8-1 includes a third region 26 and a fourth region 27 arranged along the first direction x.

The side traces 7 include a second side trace 13 electrically connected to the first pad 8. In the second side trace 13 electrically connected to the first sub-pad 8-1, the second side trace 13 of the first surface 2 overlaps with the third region 26 and does not overlap with the fourth region 27.

Before and/or after forming the side traces 7, the manufacturing method further includes: contacting the fourth region 27 of the first sub-pad 8-1 and applying a detection voltage to the first sub-pad 8-1 by a probe of a second test device, so as to test the signal line 5 connected to the first sub-pad 8-1.

For example, in the manufacturing process of the display panel, after forming the signal lines 5 and the pads 6, the resistance and other parameters of the signal lines 5 can also be tested to detect whether there is a short circuit or open circuit in the signal lines 5, and then to detect whether the display panel is qualified.

This detection process can be performed before the formation of the side traces 7. For example, on the production line of the display panel 200, the signal lines 5 can be detected as above before the formation of the side traces 7. For example, during the detection process, a probe of the second test device is placed on the pad 6 connected to a certain signal line 5, and another probe is placed on the pad 6 connected to another single line 5. If an abnormal electrical signal is detected between the two signal lines 5, it means that there is a short circuit between the two signal lines 5.

The detection process can also be performed after the formation of the side traces 7. For example, after the display panel leaves the factory, it may be returned to the factory based on customer feedback, and the signal lines 5 need to be retested after return. During retesting, because the side traces 7 have been formed in the display panel, the probe of the second test device is directly placed on the side traces 7 overlapping with the pads 6 to complete the detection.

The first pad 8 includes the fourth region 27 that does not overlap with the second side trace 13. When the signal lines 5 are detected, the fourth region 27 can be used to contact the probe of the test device. Regardless of whether the detection process is performed before or after the side traces 7 are formed, the probe of the test device can be directly placed on the fourth region 27 of the first pad 8, thereby avoiding scratches at the overlap position of the first pad 8 and the second side trace 13, and avoiding the display being affected by the poor connection between the first pad 8 and the second side trace 13.

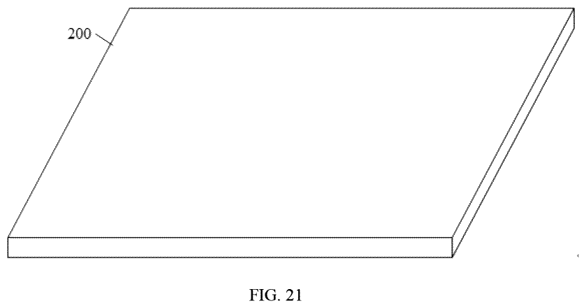

Based on the same inventive concept, an embodiment of the present disclosure also provides a display apparatus. As shown in FIG. 21, which is a structural schematic diagram of a display apparatus provided by an embodiment of the present disclosure, and the display apparatus includes the above-mentioned display panel 200. Of course, the display apparatus shown in FIG. 21 is only for schematic illustration, and the display apparatus can be any electronic device with a display function, such as a mobile phone, a tablet computer, a laptop computer, an e-book or a television.

The above description is merely preferred embodiments of the present disclosure, and is not intended to limit the present disclosure. Any modification, equivalent substitution, improvement, etc. made within the spirit and principle of the present disclosure shall fall within the protection scope of the present disclosure.

It should be noted that the above embodiments are merely used to illustrate the technical solutions of the present disclosure, rather than to limit it. Although the present disclosure has been described in detail with reference to the above embodiments, those skilled in the art should understand that they can still modify the technical solutions described in the above embodiments, or replace some or all of the technical features therein by equivalents. However, these modifications or replacements do not make the essence of the corresponding technical solutions deviate from the scope of the technical solutions of the embodiments of the present disclosure.

What is claimed is:

1. A display panel, comprising:
a substrate, wherein the substrate comprises a first surface and a second surface opposite to each other, and a first side face located between the first surface and the second surface;
a plurality of signal lines and a plurality of pads both located on the first surface, wherein the plurality of pads are located on a side of the plurality of signal lines close to the first side face, and at least part of the plurality of pads are electrically connected to the plurality of signal lines respectively; and
a plurality of side traces arranged on the first surface, the first side face, and the second surface, wherein the plurality of side traces are electrically connected to the plurality of pads respectively;
wherein the plurality of pads comprise first pads and second pads arranged along a first direction, and along the first direction, a width of one of the first pads is greater than a width of one of the second pads.

2. The display panel according to claim 1, wherein the first pads are further electrically connected to the plurality of signal lines respectively;
the plurality of side traces comprise first side traces electrically connected to the second pads respectively; and
the display panel comprises at least one test unit comprising two test groups, the two test groups respectively comprise one second pad and one first side trace electrically connected to each other, and the two test groups in one test unit are connected to each other through a first connecting line.

3. The display panel according to claim 2, wherein the substrate comprises a first edge extending along a second direction, the second direction intersects with the first direction, and at least part of the second pads are located between the first edge and the first pads.

4. The display panel according to claim 3, wherein a distance between the first edge and a second pad of the second pads adjacent thereto is greater than a distance between two adjacent pads of the plurality of pads along the first direction.

5. The display panel according to claim 3, wherein a distance between the first edge and a second pad of the second pads adjacent thereto is d, and 600 μm≤d≤700 μm.

6. The display panel according to claim 3, wherein the substrate further comprises a second edge, the second edge is opposite to the first edge along the first direction, and part of the second pads are located between the first pads and the second edge; and
a distance between the second edge and a second pad of the second pads adjacent thereto is equal to a distance between the first edge and a second pad of the second pads adjacent thereto.

7. The display panel according to claim 2, comprising:
a first area and a second area, wherein the first pads are located in the first area, and the second pads are located in the second area; and
wherein a distance between two adjacent second pads in the second area is less than a distance between two adjacent first pads in the first area, and/or a distance between two adjacent second pads in the second area is less than a distance between a first pad and a second pad of the plurality of pads that are adjacent to each other.

8. The display panel according to claim 7, wherein the distance between two adjacent second pads in the second area is d1, and 20 μm≤d1≤70 μm;
the distance between two adjacent first pads in the first area is d2, and 50 μm≤d2≤80 μm; and
the distance between the first pad and the second pad of the plurality of pads that are adjacent to each other is d3, 50 μm≤d3≤80 μm.

9. The display panel according to claim 2, wherein in one test unit, first side traces in the two test groups are connected to each other through the first connecting line, and the first connecting line is located on the second surface.

10. The display panel according to claim 9, further comprising:
test traces located on the first surface, wherein the test traces are electrically connected to the second pads respectively, and an edge of one of the test traces is flush with an edge of the substrate.

11. The display panel according to claim 9, wherein one of the second pads comprises a first region and a second region arranged along a second direction, and the second direction intersect with the first direction; and
a portion of one of the first side traces located on the first surface overlaps with the first region and does not overlap with the second region.

12. The display panel according to claim 11, wherein a width of the second region is greater than a width of the first region along the first direction.

13. The display panel according to claim 1, wherein the first pads comprise a first sub-pad, and the first sub-pad comprises a third region and a fourth region arranged along the first direction; and
the plurality of side traces comprise second side traces electrically connected to the first pads respectively, wherein in a second side trace of the second side traces electrically connected to the first sub-pad, a portion of the second side trace located on the first surface overlaps with the third region and does not overlap with the fourth region.

14. The display panel according to claim 13, wherein a width of the fourth region is less than a maximum line width of the portion of the second side trace located on the first surface along the first direction.

15. The display panel according to claim 13, wherein the plurality of pads respectively comprise a first metal portion and a second metal portion, the first metal portion overlaps with a respective one of the second side traces, and the second metal portion is located on a side of the first metal portion close to the substrate; and
wherein in the first sub-pad, the second metal portion is located in the third region and the fourth region.

16. The display panel according to claim 1, further comprising:
first traces located on the first surface, wherein the first traces are electrically connected to the first pads respectively, the first traces are located on a side of the first pads close to the first side face, and an edge of one of the first traces is flush with an edge of the first side face; and
the plurality of side traces comprise second side traces electrically connected to the first pads respectively, and a portion of one of the second side traces located on the first surface overlaps with a respective one of the first traces along a direction perpendicular to a plane of the substrate.

17. The display panel according to claim 1, wherein the first pads comprise a first sub-pad and a second sub-pad, and a width of the first sub-pad is greater than a width of the second sub-pad along the first direction.

18. The display panel according to claim 17, wherein the plurality of side traces comprise second side traces electrically connected to the first pads respectively, the second side traces respectively comprise a first line segment at least located on the first surface and a second line segment at least located on the first side face;
in a second side trace electrically connected to the first sub-pad, a width of the first line segment is greater than a width of the second line segment along the first direction; and
in a second side trace electrically connected to the second sub-pad, a width of the first line segment is less than a width of the second line segment along the first direction.

19. The display panel according to claim 1, wherein a width of one of the second pads is less than or equal to half a width of one of the first pads along the first direction.

20. A display apparatus, comprising a display panel;
wherein the display panel comprises:
a substrate, wherein the substrate comprises a first surface and a second surface opposite to each other, and a first side face located between the first surface and the second surface;
a plurality of signal lines and a plurality of pads both located on the first surface, wherein the plurality of pads are located on a side of the plurality of signal lines close to the first side face, and at least part of the plurality of pads are electrically connected to the plurality of signal lines respectively; and
a plurality of side traces arranged on the first surface, the first side face, and the second surface, wherein the plurality of side traces are electrically connected to the plurality of pads respectively;
wherein the plurality of pads comprise first pads and second pads arranged along a first direction, and along the first direction, a width of one of the first pads is greater than a width of one of the second pads.
